(19) United States
(12) Patent Application Publication
(10) Pub. No.: US 2016/0370423 A1
(43) Pub. Date: Dec. 22, 2016

(54) TESTING DEVICE FOR ELECTRICALLY TESTING AN ELECTRICAL TEST SPECIMEN

(71) Applicant: FEINMETALL GMBH, Herrenberg (DE)

(72) Inventors: Ulrich GAUSS, Herrenberg (DE); Joachim NEUBAUER, Gärtringen (DE); Stefan TREUZ, Bodelshausen (DE); Jürgen HAAP, Mössingen (DE)

(73) Assignee: FEINMETALL GMBH, Herrenberg (DE)

(21) Appl. No.: 14/901,466

(22) PCT Filed: Apr. 15, 2014
(86) PCT No.: PCT/EP2014/057671

§ 371 Date: Dec. 28, 2015

(30) Foreign Application Priority Data
Jun. 29, 2013 (DE) 10 2013 010 934.5

(51) Int. Cl. G01R 31/28; G01R 1/04; G01R 1/067

(52) U.S. Cl. CPC G01R 31/2891; G01R 1/0675; G01R 31/2884; G01R 1/0491

(57) ABSTRACT

A testing device for electrically testing an electrical test specimen, in particular a wafer, the testing device having a test head in which at least one testing contact is mounted for electrically contacting a test specimen. At least one outlet opening for discharging a gas, in particular a protective gas, into a contact region, is provided in a wall of the test head.

The invention relates to a testing device for electrically testing an electrical test specimen, in particular a wafer, the testing device having a test head in which at least one testing contact is mounted for electrically contacting the test specimen.

The testing device of the aforementioned type is used to electrically test the electrical test specimen, which is present in the form of, for example, a wafer or an electric circuit formed on the wafer. The testing contact is brought into contact with the test specimen in order to perform the test. The testing contact is, for example, a buckling needle. In such a case, an end of the buckling needle is used to contact the test specimen. The opposite end, in turn, can be or is electrically connected to a terminal contact surface of a contact device of the testing device. Preferably, the testing device has a plurality of testing contacts.

During the test, the testing contact comes into, for example, contact with a testing contact surface of the test specimen. The testing contacts comprised by the testing device are therefore equal in number to or greater in number than the testing contact surfaces comprised by the test specimen. The testing contact surface, which is formed on the test specimen or on the wafer, is composed preferably of an electroconductive and in particular metallic material, e.g., aluminum, copper, or the like. When in contact with air, however, such a material will form an oxide layer on a surface thereof. This oxide layer needs to be removed before the electric testing by means of the testing contact can be performed. The testing contact is thus subjected to intense mechanical stress and to wear, which considerably shortens the service life thereof.

An example known from the prior art is patent publication DE 10 2005 035 031 A1, which illustrates a device for testing a plurality of integrated semiconductor circuits on wafers, wherein at least one separately formed nozzle is provided in order to introduce a purging gas onto the wafer surface.

The present invention addresses the problem of providing a testing device that prolongs the service life of the testing contact and also further improves the reliability of contact between the test specimen and the testing contact.

The problem is solved according to the invention with a testing device having the features of claim 1, which provides that at least one outlet opening for discharging a gas, in particular a protective gas, into a contact region is provided in a wall of the test head. In the contact region, the test specimen is contacted by the testing contact. The contact region thus preferably comprises exactly or no less than that region in which the testing contact is in contact with the test specimen.

The outlet opening is, for example, a part of an outlet channel or formed from one. Preferably, if there are a plurality of outlet openings, a separate outlet channel is allocated for each outlet opening. The outlet channel extends through the test head, and in particular through a guide plate of the test head, so as to form at least a part of, or, in particular, the entirety of the outlet opening. Particularly preferably, the outlet channel is then formed directly in the material of the guide plate or machined out of said material. The outlet opening according to the invention can thereby be realized particularly easily. Overall, therefore, an already-present component—namely, the test head or the guide plate—is used to introduce the gas into the contact region. No additional nozzle elements or the like are needed.

Discharging the gas into the contact region makes it possible to reduce corrosion or oxidation of the test specimen, such that the testing contact is subjected to less mechanical stress when the testing contact surface is being cleaned. A consequence thereof is less contamination, in turn making it possible to increase the intervals between cleanings of the testing device. The gas also significantly reduces corrosion or oxidation of the testing contacts, and in particular on the side thereof that comes into contact with the electrical test specimen. Overall, therefore, a longer service life of the testing contacts is achieved. There is also improved reliability of electrical contact between the testing contact and the test specimen.

The gas may be, for example, for purging and/or cooling the testing device, in particular, the at least one testing contact and/or the electrical test specimen. Corrosion and/or oxidation may already have been reduced in this manner, because this is usually dependent on temperature. In particular, air is used as the gas for the purpose of purging or cooling. Preferably, with such an approach, the gas has a certain temperature that is achieved by, for example, temperature control of the gas by means of a temperature control device.

A protective gas may be employed as the gas if a further protective effect is to be achieved. As such a protective gas, it is possible, in principle, to use any gas that reduces or—at sufficient concentration in the contact region—can completely prevent corrosion or oxidation. It is preferable to use an inert gas, e.g., nitrogen or a noble gas, as the protective gas.

The outlet opening through which the gas is to be discharged into the contact region is formed in the wall of the test head. This means that at least in part, the gas flows through the test head before exiting into the contact region through the outlet opening. This arrangement of the outlet opening is advantageous in that the gas can be measured out and/or positioned with high precision. A suitable arrangement of the outlet opening or optionally the plurality of outlet openings therefore makes it possible to adjust the desired concentration and/or desired flow velocity of the gas in a targeted manner in the contact region. Preferably, a plurality of outlet openings are provided. If a plurality of testing contacts are provided, then the desired concentration and/or flow velocity of the gas can be adjusted in the contact region of at least a plurality of the testing contacts, in particular every testing contact, in a manner independent of the contact regions of the other testing contacts.

More specifically, the testing contact is mounted, for example, in a test head that is arranged, in particular, between a contact device of the testing device and the test specimen. Then, for example, in order to electrically contact the test specimen, the testing contact can be connected to a terminal contact surface of the contact device with one side thereof and can be brought into contact with the test specimen, and in particular the testing contact surface of the test specimen, with the other opposite side thereof. In this respect, during the electrical testing, an electrical connection is established via the testing contact between the test specimen and the contact device, in particular, between the testing contact surface of the test specimen and the terminal contact surface of the contact device. The gas is preferably discharged in the direction of the test specimen via the outlet opening. For this purpose, the wall in which the outlet opening is formed may face the test specimen. In the manner described above, it is possible to directly supply the gas in the region of the test specimen, namely, in the contact region.

An advantageous embodiment of the invention provides that the testing device comprises a contact device having a terminal contact surface that can be electrically connected or is electrically connected to a side of the testing contact facing away from the test specimen. The electrical test specimen preferably comprises a separate terminal contact surface for each testing contact of the testing device. As already stated above, the testing contact can be brought into contact with the test specimen with one side. The other side of the testing contact, which therefore faces away from the test specimen, can be electrically connected or is electrically connected to the associated terminal contact surface of the contact device.

In the former case, there is, for example, contact provided between the terminal contact surface and the testing contact during the electrical testing of the test specimen. The electrical connection therefore need not permanently exist in such a case, but rather only temporarily during the testing. Alternatively, it shall be readily understood as well that a permanent electrical connection may be provided between the terminal contact surface and the testing contact.

A preferred embodiment of the invention provides that the contact device and the test head are part of a testing card, and in particular a vertical testing card. The testing card is, for example, arranged in the testing device so as to be replaceable. Existing as a part of the vertical testing card, the test head preferably possesses the guide plate and a holding plate placed at a distance therefrom, the guide plate and holding plate being each penetrated at least partially but in particular completely by the testing contact in the axial direction thereof. The guide plate and the holding plate thus guide the testing contact or the testing contacts in the vertical direction.

Another embodiment of the invention provides that the wall is part of a guide plate in which there is provided at least one guide recess in which the testing contact is mounted. The wall corresponds, in particular, to a side or surface of the guide plate that faces the test specimen. The guide plate is preferably present between the contact device and the test specimen. The testing contact is arranged in the guide recess, and in particular arranged so as to be longitudinally displaceable. The guide recess extends thereto through the guide plate and therefore through the wall.

The guide plate is used to guide or support the at least one testing contact, in particular, a plurality of testing contacts of the testing device. The guide plate therefore ensures that the testing contacts are arranged so as to be reliably able to be brought into electrical contact with the test specimen, and therefore are in contact with the testing contact surface of the test specimen during the electrical testing. Preferably, the guide plate is provided in the region of the contact region or delimits same in the direction of the contact device.

A refinement of the invention provides that an outlet channel constituting the outlet opening passes through the guide plate. As already explained, the guide plate is used to reliably arrange the at least one testing contact during the electrical testing of the test specimen. In this regard, it is preferable for only a small distance to be provided between the guide plate and the test specimen, wherein, for example, the guide plate delimits the contact region. Arranging the outlet opening in the guide plate therefore makes it possible to discharge the gas into the immediate vicinity of the electrical test specimen, in particular, directly into the contact region. The outlet opening is formed by the outlet channel and is a part thereof. In particular, the outlet opening constitutes the end of the outlet channel facing the test specimen. The outlet channel preferably extends completely through the guide plate. Particularly preferably, the outlet channel is formed directly in the material of the guide plate or incorporated thereinto.

A further embodiment of the invention provides that in the test head, a chamber that has a flow connection to the outlet opening is provided. This chamber is used to supply the gas to the at least one outlet opening. Preferably, in the test head, a plurality of outlet openings are provided, at least two and in particular all of which have a flow connection to the chamber. Preferably, in the test head, there exists only one single chamber, which also particularly preferably has a flow connection to all of the outlet openings of the test head. The chamber preferably has a larger cross-section than the outlet opening. Particularly preferably, the flow connection between the chamber and the outlet opening exists via the outlet channel.

It may additionally be provided that the chamber is penetrated by the at least one testing contact. This means that at least one region of the testing contact is present in the chamber or extends from one end of the chamber to the opposite end of the chamber. If the testing contact is embodied as a buckling needle, then a buckling region of the testing contact is preferably found in the chamber. Provided in the buckling region is a deformation of the testing contact in the radial direction, relative to a longitudinal-central axis of the testing contact, in order to alter the length of the testing contact. The deformation is configured such that when a sufficiently heavy load is applied in the axial direction, the buckling needle buckles and therefore is at least partially deformed in the radial direction, such that a change in the length of the buckling needle is realized. The chamber therefore is sized so as to allow the testing contact to be deformed in a manner corresponding to the desired change in length of the testing contact.

Another embodiment of the invention provides that the chamber is at least partially delimited by the guide plate. In particular, this is provided in the direction of the test specimen. In this manner, the chamber can be realized with a relatively simple configuration of the test head.

A preferred embodiment of the invention provides that the outlet opening has a flow connection to a gas supply line via the chamber. The gas is supplied to the outlet opening via the chamber. If a plurality of outlet openings are provided, then the chamber serves to distribute the gas, which is introduced into the chamber via the gas supply line, to the plurality of outlet openings in a uniform manner. The chamber preferably has a greater cross-section with respect to a direction of flow of the gas than the outlet opening, so as to be able to serve in this regard as a settling chamber for the gas that has introduced thereinto. Overall, in this regard, the flow connection between the gas supply line and the outlet opening preferably occurs via the chamber and also via the outlet channel.

A further embodiment of the invention provides that the terminal contact surface is allocated to a contact spacing transformer. The contact device thus possesses the contact spacing transformer, which may also be referred to as a “space transformer.” The contact spacing transformer is intended to provide a simple manner of electrically contacting the terminal contact surface. For this purpose, the contact spacing transformer possesses a plurality of terminal contact surfaces, which are present at a first spacing apart from one another.

A terminal of the contact spacing transformer is electrically connected to each terminal contact surface, wherein there are accordingly a plurality of these terminals present. The terminals are then arranged on the contact spacing transformer at a second spacing apart from one another, wherein this second spacing is greater than the first spacing. For example, the terminal contact surfaces are arranged so as to be radially inward with respect to an imaginary line lying perpendicular to the test specimen, whereas the terminals are provided radially outward.

A preferred embodiment of the invention provides that the gas supply line runs through the contact device, and in particular through the contact spacing transformer. Arranging the gas supply line in this manner enables a particularly simple and flexible guidance of the gas supply line. For example, it is possible to realize a modular system in which the gas supply line is divided into a first region provided in the contact device and a second region present in the test head. The electrical testing is implemented by arranging the test head in such a manner relative to the contact device that both regions are aligned with one another so as to produce a sealed flow connection between both regions of the gas supply line. Such a configuration of the testing device accordingly makes it possible to replace the test head without taking any special measures as regards the gas supply line.

Another embodiment of the invention may provide that the gas supply line flows into the chamber through a side wall or through a holding plate of the test head that faces the contact device. For example, the test head thus comprises the guide plate and the holding plate, which are spaced apart from one another across the side wall. In particular, the chamber is delimited or enclosed by the guide plate, the holding plate, and the side wall, together.

The gas supply line can then open out into the chamber in a variety of different manners. In a first variant, the gas supply line passes through the side wall or is connected to a breach of the side wall that opens out into the chamber. In a second variant, which is preferably implemented when the gas supply line runs through the contact device, the gas supply line extends through the holding plate of the test head or is connected to a breach of the holding plate. The holding plate then faces the contact device, and in particular lies flat thereagainst. Therefore, the previously described second region of the gas supply line may be formed in the holding plate of the test head.

A further embodiment of the invention provides that the outlet channel comprises a longitudinal center line extending perpendicular to the guide plate or angled relative thereto. The longitudinal center line defines the center of the outlet channel along the longitudinal extension thereof. Preferably, the longitudinal center line is straight over the entire extension of the outlet channel, because then the pressure in the outlet channel can be minimized as much as possible. Alternatively, it shall also be readily understood that an at least partially curved longitudinal centerline of the outlet channel can be implemented. The longitudinal centerline of the outlet channel may then be perpendicular to the guide plate or to an imaginary plane lying parallel to the guide plate or a direction of greatest extension of the guide plate. For example, the longitudinal centerline of the outlet channel is present parallel to a longitudinal centerline of the at least one guide recess for the testing contact, in such a case.

Alternatively, it shall also be readily understood that the longitudinal centerline of the outlet channel may be angled relative to the guide plate or the imaginary plane, and thus enclose therewith an angle of less than 90° but greater than 0°. In other words, the longitudinal center line has an angle of more than 0° but less than 90° to the normal direction of the guide plate or the imaginary plane. In the former case, in which the longitudinal center line is perpendicular to the guide plate, the above-defined angle amounts to 90° or 0°. In particular, the angle is selected so as to achieve the desired concentration of the gas and/or the desired flow velocity in the contact region.

Another embodiment of the invention provides that the outlet channel has a cross-sectional area of flow that is constant along the longitudinal center line thereof. The outlet channel then is present as a hole having a constant diameter, which, in particular, passes completely through the guide plate in the direction of the longitudinal centerline of the outlet channel.

Alternatively, however, it may also be provided that the outlet channel has a cross-sectional area of flow that increases or decreases along the longitudinal center line thereof. The increase or decrease in the cross-sectional area of flow is then provided in the direction of the test specimen, i.e., on the side facing away from the contact device. For example, the increase or decrease in the cross-sectional area of flow is provided continuously along the longitudinal center line, so as to produce a funnel-like shape of the outlet channel. In the case where the cross-sectional area of flow increases, the outlet channel is then present as a diffuser in which the flow velocity of the gas decreases, whereas in the case where the cross-sectional area increases, it is configured as a nozzle in which the flow velocity of the gas increases in the direction of flow.

A refinement of the invention provides that the outlet opening and/or the outlet channel is/are rectangular, round, or oval as seen in cross-section. In principle, the cross-sectional shape of the outlet opening and of the outlet channel can be optionally selected. The cross-sectional shape refers to a section through the outlet opening or through the outlet channel, perpendicular to the longitudinal centerline of the outlet channel. For example, the outlet opening or the outlet channel is rectangular in cross-section, being in particular square or in the shape of a slit or longitudinal slit. Alternatively, the outlet opening or the outlet channel may be, for example, round. In such a case, the outlet opening or outlet channel is present as a hole, e.g., as a hole having a constant diameter, or a stepped hole.

Also, it shall be readily understood that there may be an oval or stadium-shaped outlet opening, the latter referring to a cross-sectional shape with which two mutually parallel straight lines are connected at the ends via respective semicircles. The outlet channel may also be configured in this manner. If a plurality of outlet openings or outlet channels are provided, then these may have at least partially different cross-sectional shapes or identical cross-sectional shapes.

A further advantageous embodiment of the invention provides that the guide recess is allocated to a testing region in which the testing contact protrudes out from the guide recess on the side of the test head that faces the test specimen. The testing region ultimately designates the region of the test head in which the guide recess and/or the guide recess is/are formed. If a testing contact is arranged in the guide recess, then the latter projects out from the test head in the testing region in such a manner as to extend in the direction of the test specimen or as to face same.

The testing region may be understood to be, for example, an envelope or an enveloping line of all the guide recesses that are allocated to the testing region. The envelope may be identified, for example, by the bordering of the at least one guide recess with an imaginary elastic band that then runs along the envelope. If only a single guide recess is allocated to the testing region, then the testing region therefore corresponds to the mouth of this guide recess on the side facing the test specimen. It is preferably provided that the imaginary elastic band is snug against the guide recesses on all sides of the testing region.

It shall be readily understood that there may be a plurality of testing regions provided on the test head, at least one testing contact being allocated to each thereof. This is particularly advantageous if a plurality of test specimens are to be inspected or tested by means of the testing device in a single test. Preferably, therefore, such a testing region is allocated for each test specimen. An embodiment of the test head that has a plurality of testing regions is then referred to as a multi-DUT test head (DUT, from “device under test”, i.e., a test specimen). It should then be noted, however, that of course a test specimen need not be allocated for every testing region during a test. The testing regions are preferably activated or deactivated in accordance with the present test specimens.

This may also be the case, mutatis mutandis, for at least one outlet opening, which is allocated to the respective testing region. For example, the outlet opening is only used for discharging gas when the testing region is active, i.e., is employed for testing a test specimen.

An exemplary embodiment of the invention provides that a plurality of guide recesses are allocated to the testing region or to each of the testing regions. Also preferably, a testing contact is allocated to each of the guide recesses. In this case, a plurality of testing contact surfaces of the test specimen can be contacted simultaneously.

A preferred embodiment of the invention provides that the plurality of guide recesses are arranged along a closed line. The closed line may have essentially any shape. The guide recesses arranged therealong are provided at a certain spacing apart from one another, wherein the spacing may be at least sectionally constant or at least sectionally different along the line. In particular, the spacing between guide recesses that are immediately adjacent to one another is constant along the line.

It may then be provided that the testing region is at least sectionally delimited or even enclosed by a plurality of guide recesses. An outer boundary of the testing region is therefore defined, especially in the manner described above, by the guide recesses that are allocated to the testing region and in particular are arranged around the testing region. For example, the plurality of guide recesses are provided in a rectangular arrangement, a circular arrangement, or an oval arrangement. This should be understood to mean that the intersection points of the longitudinal center lines of the plurality of guide recesses with a plane, and in particular a plane in the testing region, are arranged such that when the intersection points are connected with imaginary straight lines, then a rectangle, a circle, or an oval is formed.

A further advantageous embodiment of the invention provides that a plurality of testing regions are provided on the test head. The plurality of testing regions may each be configured, for example, in accordance with the above embodiments, such that in particular, each of the plurality of testing regions is delimited or bordered by a plurality of guide recesses. The guide recesses may then be present in any arrangement, e.g., in the rectangular arrangement, a circular arrangement, or another.

A particularly advantageous embodiment of the invention provides that the testing region is at least partially bordered by a plurality of outlet openings. The bordering of the testing region by the outlet openings makes it possible to generate a kind of flow curtain which achieves a particularly efficient shielding of the contact region from the external atmosphere present in an external environment.

A preferred refinement of the invention provides that the outlet opening or the plurality of outlet openings is/are arranged such that the gas discharged therethrough forms a gas curtain that at least partially delimits and in particular envelopes the contact region against an external atmosphere. The external atmosphere refers in particular to the atmosphere in the external environment of the testing device, which is present, for example, in the form of ambient air and is at room temperature. The gas curtain is intended to be formed in order to protect the contact region against the influence of the external atmosphere. It shall then be readily understood that it is particularly preferable for the gas curtain or a plurality of gas curtains to be formed such that the contact region is completely covered by the gas curtain, as seen in the circumferential direction or in plan view.

Additionally or alternatively, it may be provided that the outlet opening is arranged between a plurality of guide recesses, and in particular is at least partially enclosed thereby. With such an arrangement, the outlet opening is arranged, for example, in approximately the center or exactly the center of the testing region. If a plurality of testing regions are provided, then each testing region may comprise such an outlet opening, in particular, a central outlet opening. With such an arrangement of the outlet opening, a flow of gas going outward from the outlet opening can be generated such that a flow of the gas continuously flows through the testing region or the contact region.

It may furthermore be provided that a centrally arranged outlet openings is respectively allocated to a plurality of testing regions, and in particular all of the testing regions, and at least some of the testing regions, in particular all of the testing regions, are surrounded together by a plurality of outlet openings. In this regard, the advantages according to the foregoing embodiments are combined. The respective outlet openings arranged in the testing regions achieve a constant flow of gas through the contact region. At the same time, however, that portion of the testing regions that is enclosed together by the plurality of outlet openings is provided by a flow curtain against the influence of the external atmosphere of the external environment. The term “centrally” does not necessarily refer to a precisely central arrangement of the outlet opening in the testing region, although such an arrangement may be intended. Instead, the outlet opening is to be present at first only in the testing region, but preferably at a spacing apart from the borders thereof.

Finally, a tempering device for heating or cooling the gas may be provided upstream of the outlet opening. The temperature device is provided upstream of the outlet opening relative to the direction of flow of the gas, such that heating or cooling can bring the gas to a certain temperature prior to exiting the outlet opening. In particular, the gas is heated in order to be able to carry out a high-temperature test of the test specimen without the gas too intensely cooling down the testing device or the test head and/or the test specimen. In particular, the tempering device brings the gas to a temperature that corresponds to or at least almost corresponds to that of the test head and/or of the test specimen.

It shall be readily understood that the invention is also directed toward a method for operating a testing device for electrically testing an electrical test specimen, in particular, a wafer. The testing device comprises a test head in which at least one testing contact for electrically contacting the test specimen is mounted. The testing device is characterized in that a gas is discharged through at least one outlet opening into a contact region, wherein the outlet opening is formed in a wall of the test head. In other words, at least one outlet opening for discharging a gas into a contact region is provided in a wall of the test head. The discharging of the gas is then provided at least during the electrical contacting. It is, however, particularly advantageous for the gas to also be discharged for a certain period of time before and/or a certain period of time after the electrical contacting.

The advantages of such an approach or such a configuration of the testing device have already been discussed. It shall be readily understood that the testing device and the method may be further developed in accordance with the foregoing embodiments, such that reference is made thereto.

The invention shall be described in greater detail by the exemplary embodiments depicted in the drawings, but without limiting the invention.

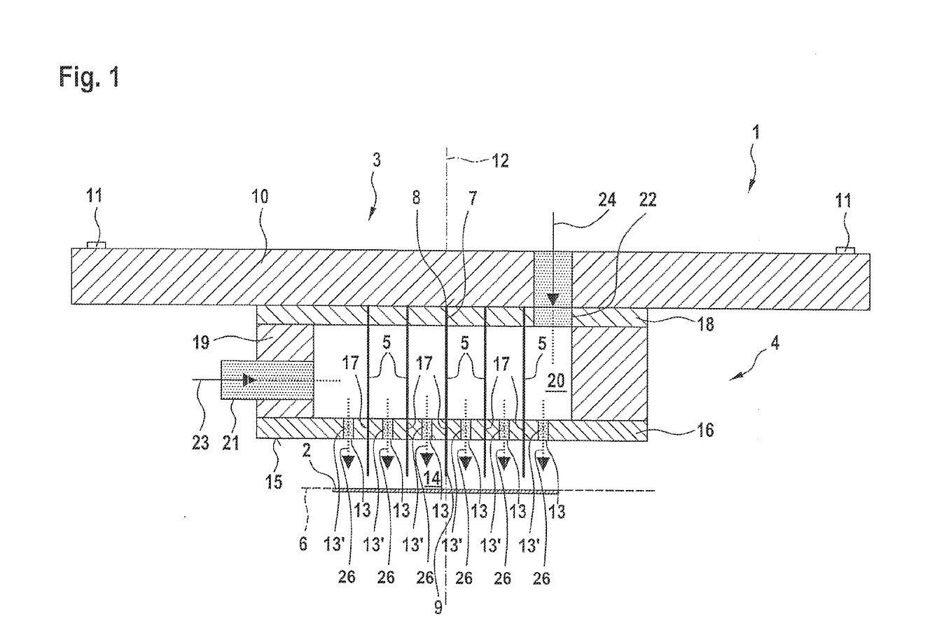

FIG. 1 illustrates a schematic cross-sectional view of a testing device for electrically testing an electrical test specimen, wherein at least one outlet opening for discharging a gas is provided;

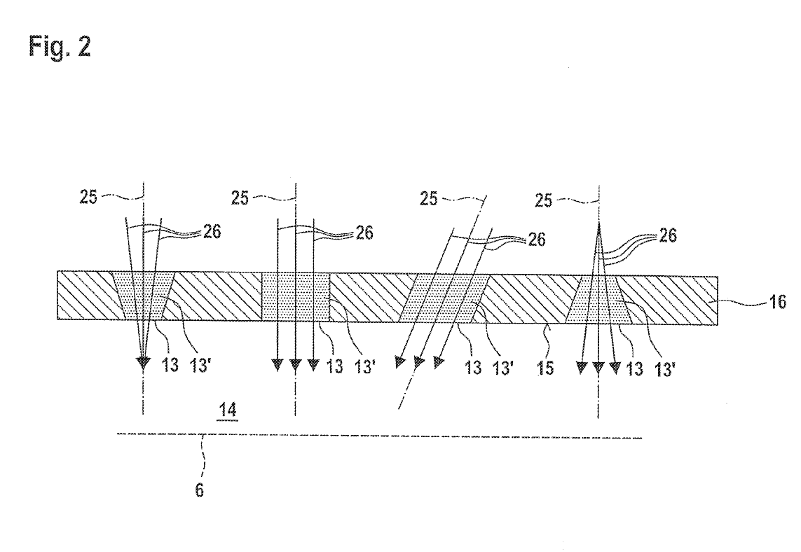

FIG. 2 illustrates a cross-section through a region of the testing device, wherein outlet openings having different cross-sectional shapes are represented;

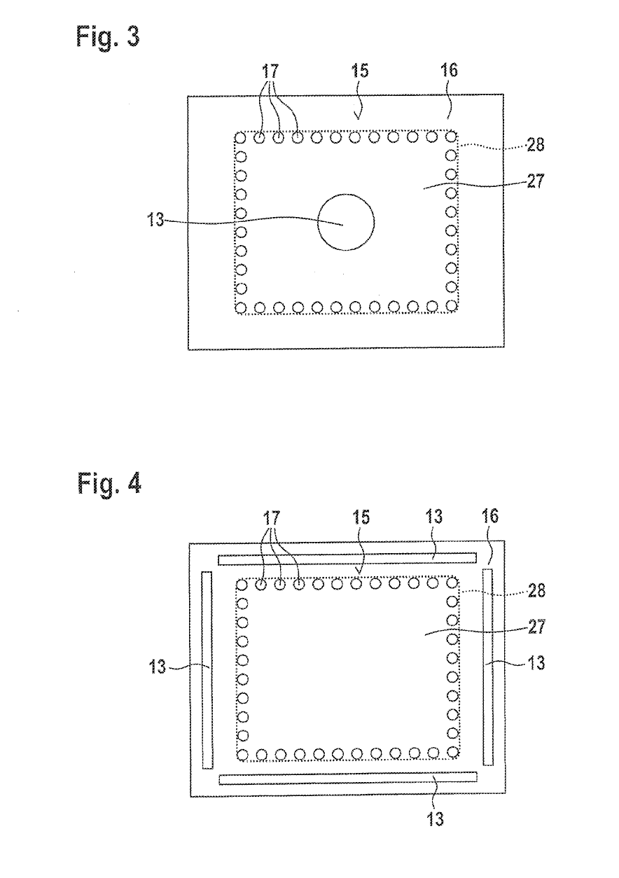

FIG. 3 illustrates a first arrangement variant of the outlet opening and a plurality of guide recesses;

FIG. 4 illustrates a second arrangement variant, in which a plurality of outlet openings are provided;

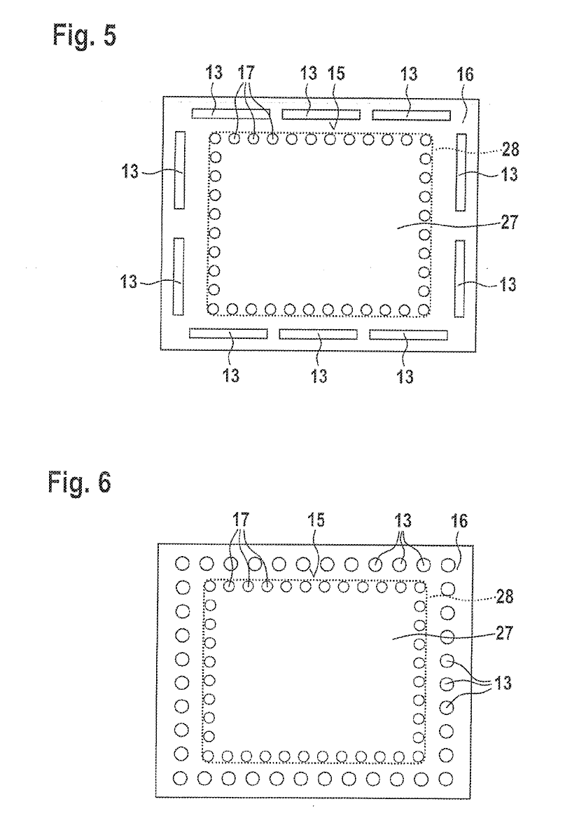

FIG. 5 illustrates a third arrangement variant;

FIG. 6 illustrates a fourth configuration variant;

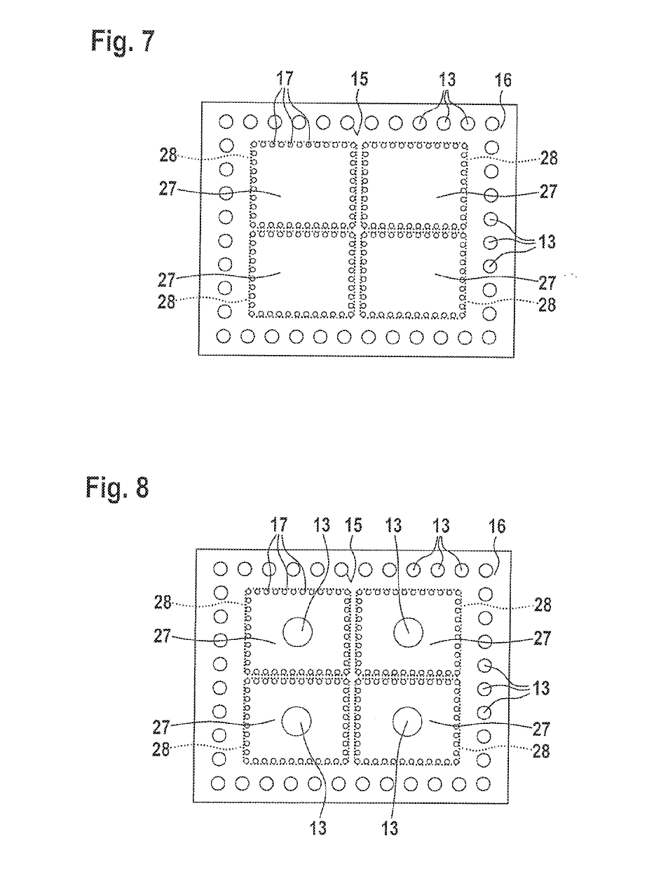

FIG. 7 illustrates a fifth configuration variant; and

FIG. 8 illustrates a sixth arrangement variant.

FIG. 1 illustrates a schematic cross-sectional view of a testing device 1 for electrically testing a test specimen 2, which is only implied here. The testing device 1 comprises, for example, a testing machine (not shown here; also known as a “prober”), in which a contact device 3 is inserted. The contact device 3 is preferably inserted by means of a compartment construction in the testing machine, which is not depicted in greater detail. The contact device 3 is preferably configured as a testing card, and in particular as a vertical testing card. The contact device then comprises a test head 4 in which at least one testing contact 5 for electrically contacting the test specimen 2 is mounted. A plurality of such testing contacts 5 are provided in the embodiment depicted here. The testing contact 5 has, for example, a longitudinal extension that lies substantially perpendicular to a testing plane 6.

The testing contact 5 is configured, for example, as a testing needle, and in particular as a buckling needle. The testing contact then has, for example, a slight deflection in a buckling region (not shown here), and therefore deviates from a rectilinear shape. If the testing contact 4 is urged against the test specimen 2 in order to electrically contact same, then a testing contact 5 designed in this manner can be easily deflected due to the deflection in the buckling region thereof. In this manner, spacing irregularities can be balanced out during the contacting, especially if a plurality of testing contacts 5 are provided, and therefore a very high reliability of the contacting can be ensured.

In order to electrically contact the test specimen 2, the testing contact 5 or each of the testing contacts 5 can be connected or is/are connected to a terminal contact surface 8 of the contact device 3 with one side 7 thereof, and can be brought into contact with the test specimen 2 with another side 9 thereof. This is suggested here only by way of example for one of the testing contacts 5. The testing contact 5 therefore can be electrically connected or is electrically connected to the terminal contact surface 8 with the side 7 thereof, which faces away from the test specimen 5. The former refers here to a temporary electrical connection, and the latter refers to a permanent electrical connection.

The terminal contact surface 8 is allocated to, for example, a contact spacing transformer 10 of the contact device 3. The contact spacing transformer 10 is used to reliably electrically connect the testing contacts 5 or the terminal contact surfaces 8 to an evaluation unit (not shown here) of the testing device 1. For this purpose, terminals 11—of which only two are depicted here, by way of example—are respectively allocated to each of the testing contacts 5. Preferably, the terminals 11 are arranged relative to a longitudinal centerline 12 of the contacting spacing transformer 10 so as to be further outward in the radial direction than the testing contacts 5. For example, the contact spacing transformer 10 is configured so as to be circular, or has a substantially circular outer circumference.

If the test specimen 2 is contacted by means of the testing device under ambient conditions, and in particular under the influence of ambient air, then it may lead to corrosion of the test specimen 2 and/or the testing contacts 5. In order to avoid this, a gas can be discharged into a contact region 14 through at least one outlet opening 13.

The gas is discharged then at least during the electrical contacting of the test specimen 2, but preferably also during a certain period of time before and/or during a certain period of time after the contacting.

The at least one outlet opening 13—in the embodiment depicted here, a plurality of outlet openings 13 are provided—is formed in a wall 15 of the test head 4. This ensures that the gas is discharged into the contact region 14 in a targeted manner. The wall 15 then preferably faces the test specimen 2 or the testing plane 6. The “contact region 14” is to refer at least to that region in which the at least one testing contact 5 enters into contact with the test specimen 2 during the electrical contacting.

The test head 4 comprises a guide plate 16, which is preferably spaced apart from the contact device 3 or the contact spacing transformer 10. In the embodiment depicted here, the wall 15 is present on the guide plate 16. The outlet opening 13 is formed in the test head 4 or in the guide plate 16 through an outlet channel 13′. One separate outlet channel 13′ is present for each of the outlet openings 13. The outlet channel 13′ is then preferably directly produced in the material of the guide plate 16.

In the guide plate 16, there is preferably at least one guide recess 17 formed, in which the at least one testing contact 5 is mounted. Preferably, one such guide recess 17 is allocated to each of the testing contacts 5, wherein the guide recess 17 particularly preferably permits only displacement of the testing contact 5 in the longitudinal direction, as well as rotational movement.

The test head 4 furthermore has a holding plate 18 and a side wall 19. The guide plate 16 is then held relative to the holding plate 18 by the side wall 19. Then, the guide plate 16 is spaced apart from the holding plate 18 in such a manner that the guide plate 16, the holding plate 18, and the side wall 19 delimit or enclose a chamber 20. This chamber 20 is completely penetrated by the at least one testing contact 5. The testing contact 5 thus extends out from the holding plate 18 to the guide plate 16 or passes through the the guide recess 17 arranged therein, in the direction of the test specimen 2. The testing contact 5 is then fixed, for example, in the holding plate 18 while being mounted in the guide plate 16 in the manner described above. Alternatively, it shall be readily understood that the testing contact may be mounted in the holding plate 18 so as to be movable, and in particular longitudinally displaceable. The aforementioned buckling region or the deflection of the testing contact 5 is preferably present in the chamber 20.

In the embodiment of the testing device 1 depicted here, the at least one outlet opening 13 has a flow connection to the chamber 20, and in particular, the outlet opening 13 goes out from the chamber 20 or opens thereinto. The outlet opening 13 has a flow connection to a gas supply line 21 and/or 22 via the chamber 20. Typically, only one of the gas supply lines 21 and 22 is provided; however, in a special embodiment of the testing device 1, both gas supply lines 21 and 22 may be implemented in the respectively described embodiment.

The gas supply line 21 opens into the chamber through the side wall 19. Gas can be introduced therethrough into the chamber 20 in the direction of the arrow 23. The gas supply line 22, in turn, runs through the holding plate 18, and thus opens into the chamber 20 by passing therethrough. Gas can be introduced through the gas supply line 22 into the chamber 20 in the direction of the arrow 24. The gas supply line 22 passes through at least one region of the contact device 3, and in particular the contact spacing transformer 10, as is indicated here purely by way of example. It shall be readily understood that the gas supply line 22 may follow any course within the contact device 3 or the contact spacing transformer 10, and in particular, may therefore be guided radially (relative to the longitudinal center line 12) outward within the contact device 3. In this manner, it is possible to implement a simple connection of the gas supply line 22 to a gas source.

FIG. 2 illustrates a cross-section through a region of the testing device 1, wherein different cross-sectional shapes for the outlet opening 13 are depicted. Four different cross-sectional shapes are illustrated. A first cross-sectional shape, a second cross-sectional shape, a third cross-sectional shape, and a fourth cross-sectional shape are portrayed from left to right. A longitudinal center line 25 of the four different outlet openings 13 is indicated in each instance. The first, second, and fourth cross-sectional shapes each have a longitudinal center line 25 that runs perpendicular to the guide plate 16 or the wall 15. In particular, the respective longitudinal center line 25 of these cross-sectional shapes intersects the testing plane 6, in which the test specimen for electrical contacting is arranged, at a right angle.

The longitudinal center line 25 may, however, also be angled relative to the guide plate 16, the wall 15, or the testing plane 6. This is depicted here for the third cross-sectional shape. It can be clearly seen that the longitudinal center line 25 of this cross-sectional shape is not perpendicular to the aforementioned elements, and therefore closes an angle of less than 90° but greater than 0° therewith.

The outlet openings 13 and the different cross-sectional shapes may have a constant cross-sectional area of flow, or an increase or decreasing cross-sectional area of flow, along the respective longitudinal center line 25 thereof. The first cross-sectional shape has a cross-sectional area of flow that decreases going in the direction of the testing plane 6 or the test specimen 2 and, in this regard, is configured in the shape of a nozzle. The constant cross-sectional area of flow is depicted for the second cross-sectional shape as well as for the third cross-sectional shape. The cross-sectional area of flow of the fourth cross-sectional shape increases in the direction of the testing plane 6 or the test specimen 2, such that there is a diffuser shape of the corresponding outlet opening 13.

The gas can be discharged through the outlet openings 13 from the chamber 20 along the arrows 26 in the direction of the test specimen 2 and thus into the contact region 14.

The outlet opening 13 may, in principle, be optionally configured as seen in cross-section and is, for example, rectangular (in particular, the shape of a slit), round, or oval. A stadium-shaped configuration may also be provided.

Different arrangement variants for the at least one outlet opening 13 shall be illustrated with reference to FIGS. 3 to 8. FIG. 3 illustrates a first arrangement variant, in which a plurality of guide recesses 17 (of which only some are indicated, by way of example) are allocated to a testing region 27 or define same. The testing region 27 is defined, for example, by the envelope 28 of all of the guide recesses 17 allocated thereto. In the arrangement variant depicted here, therefore, the testing region 27 is surrounded by a plurality of guide recesses 17. In the testing region 27, the testing contacts 5 allocated thereto protrude out from the associated guide recesses 17 on the side of the test head 4 facing the test specimen 2.

The guide recesses 17 are provided here in a rectangular arrangement such that the testing region 27 is also rectangular. In the first arrangement variant, only a single outlet opening 13 is provided, which is preferably arranged centrally in the testing region 27. The outlet opening 13 is thus surrounded by the plurality of guide recesses 17. With such an arrangement of the outlet opening 13, it is possible to obtain a constant flow of the gas coming out from the outlet opening 13 in the direction of an external environment, such that the testing contacts 5, which protrude through the guide recesses 17, are constantly bathed by the gas stream.

FIG. 4 illustrates a second arrangement variant. Here, too, there is a testing region 27 that is defined by a plurality of guide recesses 17 in accordance with the foregoing embodiments. It is now clear, however, that in contrast to the first arrangement variant, at least one outlet opening 13 that is arranged on the outside of the testing region 27 is provided. In the embodiment depicted here, there are four outlet openings 13 implemented, which are each configured so as to be rectangular and nearly completely surround the testing region 27. The testing region 27 is at least partially, and in particular mostly, surrounded by the at least one outlet opening 13 or the plurality of outlet openings 13. For this purpose, the outlet openings 13 preferably each have a length that extends at least over the side of the testing region 27 facing same. Preferably, however, the outlet opening 13 is larger than the side of the testing region 27 facing same.

FIG. 5 illustrates a third arrangement variant. This is similar in principle to the second arrangement variant, such that the foregoing embodiments are referenced. The difference here is that at each end of the testing region, a plurality—i.e., at least two—outlet openings 13 are provided, and each extend over a part of the side length of the testing region 27.

FIG. 6 illustrates a fourth arrangement variant. Here, too, the foregoing embodiments are referenced. In contrast to the previously-described arrangement variants, there is now a plurality of outlet openings 13 that surround the testing region 27. The outlet openings 13 are preferably round as seen in cross-section.

A fifth arrangement variant is apparent from FIG. 7. This is similar to the fourth arrangement variant, such that the fourth arrangement is referenced here. Here, however, there are provided a plurality of testing regions 27 that together are surrounded by the outlet openings 13, which here are arranged analogously to the fourth arrangement variant. Alternatively, however, it is also conceivable to have an arrangement according, for example, to the second or third arrangement variants. In any case, the outlet openings 13 are present along a stretch that is larger than or equal to the common side length of the plurality of testing regions 27.

FIG. 8 illustrates a sixth arrangement variant, which, in a particularly preferable manner, combines the first arrangement variant and the fifth arrangement variant together. The foregoing embodiments are referenced. There are a plurality of testing regions 27, to each of which a centrally-arranged outlet opening 13 is allocated. At the same time, the testing regions 27 are surrounded together by the plurality of outlet openings 13. The outlet openings surrounding the testing regions 27 may, of course, be arranged in accordance with all of the previously-described arrangement variants, and in particular, analogously to the second, third, or fourth arrangement variants.

1. A testing device (1) for electrically testing a electrical test specimen (2), in particular, a wafer, the testing device (1) having a test head (4) in which at least one testing contact (5) for electrically contacting the test specimen (2) is mounted, the testing device (1) being characterized in that: at least one outlet opening (13) for discharging a gas, in particular, a protective gas into a contact region (14) is provided in a wall (15) of the test head (4).

2. The testing device according to claim 1, characterized in that: the testing device (1) comprises a contact device (3) having a terminal contact surface (8), which can be electrically connected or is electrically connected to a side (7) of the testing contact (5) that faces away from the test specimen (2).

3. The testing device according to any of the preceding claims, characterized in that: the contact device (3) and the test head (4) are part of a testing card, and in particular a vertical testing card.

4. The testing device according to any of the preceding claims, characterized in that: the wall (15) is part of a guide plate (16) of the test head (4), in which at least one guide recess (17) is provided, the testing contact (5) being mounted therein.

5. The testing device according to any of the preceding claims, characterized in that: an outlet channel (13′) forming the outlet opening (13) passes through the guide plate (16).

6. The testing device according to any of the preceding claims, characterized in that: in the test head, a chamber (20) that has a flow connection to the outlet opening (13) is provided.

7. The testing device according to any of the preceding claims, characterized in that: the chamber (20) is penetrated by the at least one testing contact (5).

8. The testing device according to any of the preceding claims, characterized in that: the chamber (20) is at least partially delimited by the guide plate (16).

9. The testing device according to any of the preceding claims, characterized in that: the outlet opening (13) has a flow connection to a protective gas supply line (21, 22) via the chamber (20).

10. The testing device according to any of the preceding claims, characterized in that: the terminal contact surface (8) is allocated to a contact spacing transformer (10) of the contact device (3).

11. The testing device according to any of the preceding claims, characterized in that: the protective gas supply line (21, 22) runs through the contact device (3), and in particular, through the contact spacing transformer (10).

12. The testing device according to any of the preceding claims, characterized in that: the protective gas supply line (21, 22) opens into the chamber (20) through a side wall (19) or through a holding plate (18) of the test head (4) that faces the contact device (3).

13. The testing device according to any of the preceding claims, characterized in that: the outlet channel (13′) has a longitudinal center line (25) that is perpendicular to the guide plate (16) or is angled relative thereto.

14. The testing device according to any of the preceding claims, characterized in that: the outlet channel (13′) has a cross-sectional area of flow that is constant along the longitudinal center line (25) thereof.

15. The testing device according to any of the preceding claims, characterized in that: the outlet channel (13′) has a cross-sectional area of flow that increases or decreases along the longitudinal center line (25) thereof.

16. The testing device according to any of the preceding claims, characterized in that: the outlet opening (13) and/or the outlet channel (13′) is/are rectangular, round, or oval as seen in cross-section.

17. The testing device according to any of the preceding claims, characterized in that: the guide recess (17) is allocated to a testing region (27) in which the testing contact (5) protrudes out from the guide recess (17) on the side of the test head (4) that faces the test specimen (2).

18. The testing device according to any of the preceding claims, characterized in that: a plurality of guide recesses (17) are allocated to the testing region (27).

19. The testing device according to any of the preceding claims, characterized in that: the plurality of guide recesses (17) are arranged along a closed line.

20. The testing device according to any of the preceding claims, characterized in that: a plurality of testing regions (27) are provided on the test head (4).

21. The testing device according to any of the preceding claims, characterized in that: the testing region is at least partially enclosed by the outlet opening (13) or by a plurality of outlet openings (13).

22. The testing device according to any of the preceding claims, characterized in that: the outlet opening (13) or the plurality of outlet openings (13) is/are arranged such that the gas discharged therethrough forms a gas curtain that at least partially delimits and in particular envelopes the contact region (14) against an external atmosphere.

23. The testing device according to any of the preceding claims, characterized in that: the outlet opening (13) is arranged between a plurality of guide recesses, and in particular, is at least partially surrounded thereby.

24. The testing device according to any of the preceding claims, characterized in that: a centrally arranged outlet opening (13) is allocated to a plurality of testing regions (27), in particular, all of the testing regions (27), and at least some of the testing regions (27), in particular, all of the testing regions (27) are surrounded together by a plurality of outlet openings (13).

25. The testing device according to any of the preceding claims, characterized by a tempering device for heating or cooling the protective gas, upstream of the outlet opening (13).
